(19) United States
(12) Patent Application Publication
(10) Pub. No.: US 2022/0255089 A1
(43) Pub. Date: Aug. 11, 2022

(54) METHOD OF PRODUCING SEPARATOR

(71) Applicant: TOYOTA JIDOSHA KABUSHIKI KAISHA, Toyota-shi (JP)

(72) Inventors: Takashi AISAKA, Nisshin-shi (JP); Takashi KONO, Tajimi-shi (JP)

(21) Appl. No.: 17/648,026

(22) Filed: Jan. 14, 2022

(30) Foreign Application Priority Data
Feb. 10, 2021 (JP) 2021-019490

(51) Int. Cl. H01M 8/0228; H01M 8/021; C23C 14/58; C23C 14/16; H01M 8/0213; C23C 14/06

(52) U.S. Cl. CPC H01M 8/0228; H01M 8/021; C23C 14/0605; C23C 14/16; H01M 8/0213; C23C 14/5806

(57) ABSTRACT

The present disclosure relates to a method of producing a separator for a fuel cell in which layers having corrosion resistance and conductivity are formed on a stainless steel base material, the method including (i) a process of removing a passive layer on a surface of a stainless steel base material to obtain a stainless steel base material from which the passive layer has been removed, (ii) a process of forming layers having corrosion resistance and conductivity on the surface of the stainless steel base material from which the passive layer has been removed to obtain a corrosion-resistant conductive layer-deposited stainless steel base material, and (iii) a process of annealing the corrosion-resistant conductive layer-deposited stainless steel base material in a temperature range of 250° C. or higher and lower than 550° C. under conditions of oxygen being contained.

### CROSS-REFERENCE TO RELATED APPLICATION

This application claims priority to Japanese Patent Application No. 2021-019490 filed on Feb. 10, 2021, incorporated herein by reference in its entirety.

### BACKGROUND

### 1. Technical Field

The present disclosure relates to a method of producing a separator, and specifically, to a method of producing a separator for a fuel cell.

### 2. Description of Related Art

A fuel cell has a stack structure in which a predetermined number of single cells that generate an electromotive force according to a reaction of a fuel gas (hydrogen) and an oxidant gas (oxygen) are laminated. A single cell has a membrane electrode assembly including electrode layers (a catalyst layer and a gas diffusion layer) of an anode and a cathode on both sides of an electrolyte film and separators disposed on both sides of the membrane electrode assembly.

The separator has a function of electrically connecting single cells in series and a function of a partition wall that isolates a fuel gas, an oxidant gas and cooling water from each other.

Since the separator for a fuel cell also has a function of passing a generated current to an adjacent cell, a base material constituting the separator is required to have high conductivity and corrosion resistance. Here, high conductivity means that the contact resistance is low. In addition, the contact resistance means that a voltage drop occurs between an electrode and the surface of the separator due to an interfacial phenomenon.

Therefore, pure titanium or a titanium alloy is often used as the base material constituting the separator, which is a major factor that increases the costs of separator production.

Therefore, various studies have been conducted on separators that can replace pure titanium and a titanium alloy.

For example, Japanese Unexamined Patent Application Publication No. 2011-134653 (JP 2011-134653 A) discloses a separator for a fuel cell in which the separator includes a base material made of stainless steel, an intermediate film made of titanium formed on the surface of the base material, and an outer peripheral film made of a carbon-based material formed on the surface of the intermediate film.

WO 2012/053431 discloses a separator for a fuel cell which includes a stainless steel base material, a gold-plated layer with pinholes formed on the stainless steel base material, and a stainless steel passive layer formed in the pinholes, and has a region in which the gold-plated layer and the stainless steel base material are in contact with each other without a stainless steel passive layer therebetween.

### SUMMARY

However, there is room for improvement in conductivity and corrosion resistance for a separator for a fuel cell in which a titanium layer and a conductive layer are formed as films on the stainless steel base material.

Therefore, the present disclosure provides a method of producing a separator having low contact resistance and high corrosion resistance.

The inventors investigated factors that cause insufficient corrosion resistance in a separator for a fuel cell in which a titanium layer and a carbon layer are formed on a stainless steel base material, and found that there are a plurality of nano-order scale defective parts (also called “pinholes”) on the titanium layer on the stainless steel base material, and metal elution derived from the stainless steel base material may occur with the defective parts as starting points.

Therefore, the inventors conducted various studies regarding means for addressing the above problems, and as a result, found that, in a method of producing a separator for a fuel cell in which layers having corrosion resistance and conductivity are formed on a stainless steel base material, after a passive layer (an oxidation protective film made of a metal oxide) present on the stainless steel base material is removed, when layers having corrosion resistance and conductivity are formed on the surface of the base material, and an annealing treatment (heat treatment) is additionally performed in a certain temperature range under conditions of oxygen being contained, it is possible to produce a separator for a fuel cell having low contact resistance and improved corrosion resistance by minimizing metal elution, and completed the present disclosure.

Specifically, the gist of the present disclosure is as follows.

(1) A method of producing a separator for a fuel cell in which layers having corrosion resistance and conductivity are formed on a stainless steel base material, the method including:
(i) a process of removing a passive layer on a surface of a stainless steel base material to obtain a stainless steel base material from which the passive layer has been removed,
(ii) a process of forming layers having corrosion resistance and conductivity on the surface of the stainless steel base material from which the passive layer has been removed to obtain a corrosion-resistant conductive layer-deposited stainless steel base material, and
(iii) a process of annealing the corrosion-resistant conductive layer-deposited stainless steel base material in a temperature range of 250° C. or higher and lower than 550° C. under conditions of oxygen being contained.
(2) The method according to (1), wherein, in the process (iii), the annealing treatment is performed at 250° C. to 400° C.
(3) The method according to (1) or (2),

wherein the process (ii) includes

(ii-1) a process of forming a titanium layer on the surface of the stainless steel base material from which the passive layer has been removed to obtain a titanium layer-deposited stainless steel base material, and
(ii-2) a process of forming a carbon layer on the surface of the titanium layer-deposited stainless steel base material to obtain a titanium layer-deposited and carbon layer-deposited stainless steel base material.
(4) The method according to any one of (1) to (3),

wherein, in the process (ii), the layers having corrosion resistance and conductivity are formed by a physical vapor deposition method.

According to the present disclosure, there is provided a method of producing a separator having low contact resistance and high corrosion resistance.

### BRIEF DESCRIPTION OF THE DRAWINGS

Features, advantages, and technical and industrial significance of exemplary embodiments of the disclosure will be described below with reference to the accompanying drawings, in which like signs denote like elements, and wherein:

FIG. 1 is a diagram schematically showing a method of forming a layer having corrosion resistance and a layer having conductivity on a stainless steel base material in the related art;

FIG. 2 is a diagram schematically showing a method of forming a layer having corrosion resistance and a layer having conductivity on a stainless steel base material of the present disclosure;

FIG. 3 is a TEM image of a titanium layer 3-deposited and carbon layer 4-deposited stainless steel base material 1 obtained in 1. Sample preparation of an example;

FIG. 4 is a diagram schematically showing a contact resistance measurement device 6;

FIG. 5 is a graph showing contact resistances of Comparative Examples 1 to 4 and Examples 1 and 2; and

FIG. 6 is a graph showing elution amounts of Comparative Example 1 and Example 1.

### DETAILED DESCRIPTION OF EMBODIMENTS

Exemplary embodiments of the present disclosure will be described below in detail.

In this specification, features of the present disclosure will be appropriately described with reference to the drawings. In the drawings, sizes and shapes of respective components are exaggerated for clarity and do not accurately reflect actual sizes and shapes. Therefore, the technical scope of the present disclosure is not limited to the sizes and shapes of respective components shown in the drawings. Here, a method of producing a separator of the present disclosure is not limited to the following embodiments, and can be realized in various modes that may be modified and improved by those skilled in the art without departing from the spirit and scope of the present disclosure.

The present disclosure relates to a method of producing a separator for a fuel cell in which layers having corrosion resistance and conductivity are formed on a stainless steel base material, the method including (i) a process of removing a passive layer on a surface of a stainless steel base material to obtain a stainless steel base material from which the passive layer has been removed, (ii) a process of forming layers having corrosion resistance and conductivity on the surface of the stainless steel base material from which the passive layer has been removed to obtain a corrosion-resistant conductive layer-deposited stainless steel base material, and (iii) a process of annealing the corrosion-resistant conductive layer-deposited stainless steel base material in a certain temperature range under conditions of oxygen being contained.

The separator for a fuel cell in the present disclosure is component of a fuel cell (single cell), and is disposed on both sides of a membrane electrode assembly (an electrolyte film, and electrode layers of an anode and a cathode disposed on both sides of the electrolyte film).

The processes (i) to (iii) will be described below.

(i) A process of removing a passive layer on a surface of a stainless steel base material to obtain a stainless steel base material from which the passive layer has been removed

In the process (i), the passive layer on the surface of the stainless steel base material is removed by plasma cleaning with Ar gas to obtain a stainless steel base material from which the passive layer has been removed.

As the stainless steel base material (a base material formed of stainless steel), SUS316 having high corrosion resistance, and SUS447 and SUS304, which are cheaper than SUS316, can be used.

When an inexpensive stainless steel base material is used as the base material, the amount of titanium used can be reduced as compared with when a titanium base material is used, and the cost can be reduced.

The shape of the stainless steel base material is not limited, and a stainless steel base material that has been pressed in advance into a shape of the final separator for a fuel cell is preferable.

When a stainless steel base material that has been pressed in advance is used as the stainless steel base material, a separator for a fuel cell can be obtained without additional pressing after the corrosion-resistant conductive layer is formed.

The thickness of the stainless steel base material is not limited, and is generally 0.05 mm to 0.2 mm, and preferably 0.08 mm to 0.12 mm.

When the thickness of the stainless steel base material is set to be within this range, it is possible to reduce raw material costs. In addition, even if the stainless steel base material is press-molded after the corrosion-resistant conductive layer is formed, it can be easily press-molded.

For a method of removing the passive layer formed on the surface of the stainless steel base material, a technique known in the technical field can be used, and the method is not limited, and examples thereof include an etching treatment in an inert atmosphere.

When the passive layer formed on the surface of the stainless steel base material is removed, it becomes easy to form a corrosion-resistant conductive layer, and particularly, a titanium layer, on the surface of the stainless steel base material.

(ii) A process of forming layers having corrosion resistance and conductivity on the surface of the stainless steel base material from which the passive layer has been removed to obtain a corrosion-resistant conductive layer-deposited stainless steel base material

In the process (ii), layers having corrosion resistance and conductivity are formed on the surface of the stainless steel base material from which the passive layer has been removed to obtain a corrosion-resistant conductive layer-deposited stainless steel base material.

The layer having corrosion resistance is not limited, and examples thereof include a titanium layer and a chromium layer.

The layer having conductivity is not limited, and examples thereof include a layer containing a conductive material, for example, carbon such as carbon black, an antimony-doped tin oxide (ATO), a precious metal, tin-doped indium oxide (ITO), LaNiO₃, SrMoO₃, (La, Sr)CoO₃, LaTiO₃, MgZnO, Ta₂O, ZnMgAlO, and SrSnO₃. For conductive particles, an inexpensive carbon layer is preferable.

As the layer having corrosion resistance and conductivity, a layer having a titanium layer and a carbon layer is preferable.

When the layer having a titanium layer and a carbon layer is used as the layer having corrosion resistance and conductivity, it is possible to secure sufficient corrosion resistance and conductivity.

Therefore, the process (ii) preferably includes (ii-1) a process of forming a titanium layer on the surface of the stainless steel base material from which the passive layer has been removed to obtain a titanium layer-deposited stainless steel base material and (ii-2) a process of forming a carbon layer on the surface of the titanium layer-deposited stainless steel base material to obtain a titanium layer-deposited and carbon layer-deposited stainless steel base material.

In the process (ii-1), a titanium layer is formed on the surface of the stainless steel base material from which the passive layer has been removed to obtain a titanium layer-deposited stainless steel base material.

As a method of laminating a titanium layer on the surface of the stainless steel base material from which the passive layer has been removed, a method known in the technical field can be used, and the method is not limited, and examples thereof include a physical vapor deposition (PVD) method, for example, a sputtering method, an arc ion plating (AIP) method, and a chemical vapor deposition (CVD) method. As the method of laminating a titanium layer on the surface of the stainless steel base material from which the passive layer has been removed, a PVD method is preferable.

When the PVD method is used as the method of laminating a titanium layer on the surface of the stainless steel base material from which the passive layer has been removed, it is possible to improve the yield rate.

The thickness of the titanium layer is not limited, and the average thickness is generally 10 nm to 500 nm, and preferably 40 nm to 200 nm. The average thickness of the titanium layer can be measured, for example, as an average value of three randomly selected points in cross-section TEM observation.

When the thickness of the titanium layer is set to be within the above range, it is possible to obtain an effect of reducing the amount of titanium used while securing corrosion resistance, prevent film stress caused by formation of the titanium layer from becoming too large, and minimize the occurrence of cracks in the titanium layer and deformation of the stainless steel base material on which the titanium layer is laminated.

In the process (ii-2), a carbon layer is formed on the surface of the titanium layer-deposited stainless steel base material to obtain a titanium layer-deposited and carbon layer-deposited stainless steel base material.

As a method of forming a carbon layer on the surface of the titanium layer-deposited stainless steel base material, a method known in the technical field can be used, and the method is not limited, and examples thereof include a method in which a suspension containing carbon particles is applied to the surface of the stainless steel base material with, for example, a gravure roller or a die coater, and a solvent is then removed, and a physical vapor deposition (PVD) method, for example, a sputtering method, an arc ion plating (AIP) method, and a chemical vapor deposition (CVD) method. As the method of forming a carbon layer on the surface of the titanium layer-deposited stainless steel base material, a PVD method is preferable.

When a PVD method is used as the method of forming a carbon layer on the surface of the titanium layer-deposited stainless steel base material, it is possible to improve the yield rate.

The thickness of the carbon layer is not limited, and the average thickness is generally 5 nm to 200 nm, and preferably 10 nm to 100 nm. The average thickness of the carbon layer can be measured, for example, as an average value of three randomly selected points in cross-section TEM observation.

When the thickness of the carbon layer is set to be within the above range, it is possible to obtain an effect of reducing the amount of carbon used while securing conductivity, prevent film stress caused by formation of the carbon layer from becoming too large, and minimize the occurrence of cracks in the carbon layer and deformation of the stainless steel base material in which the titanium layer and the carbon layer are laminated.

Here, the process (ii-1) and the process (ii-2) are successively performed, and after the process (ii-2), the process (iii) to be described below in detail is performed. This is because, for example, when the process (iii) is performed after the process (ii-1) and the process (ii-2) is then performed, the surface of the titanium layer formed in the process (ii-1) is oxidized and the adhesion of the carbon layer formed in the process (ii-2) may be impaired.

(iii) A process of annealing the corrosion-resistant conductive layer-deposited stainless steel base material in a certain temperature range under conditions of oxygen being contained.

In the process (iii), the corrosion-resistant conductive layer-deposited stainless steel base material is annealed in a certain temperature range under conditions of oxygen being contained.

The conditions of oxygen being contained are not limited as long as oxygen is contained in the atmosphere in which the annealing treatment is performed, and examples thereof include an atmosphere in which the oxygen partial pressure under conditions of oxygen being contained is generally 0.1 Pa to 300,000 Pa, for example, air.

The temperature range in which the annealing treatment is performed is 250° C. or higher and lower than 550° C., and preferably 250° C. to 400° C.

The temperature condition is dominant for the annealing treatment, and the time for which the annealing treatment is performed is not limited, and is generally 0.1 hours to 3.0 hours, and preferably 0.5 hours to 1.5 hours.

When the corrosion-resistant conductive layer-deposited stainless steel base material is annealed in a certain temperature range under conditions of oxygen being contained, a favorable passive layer is formed on a plurality of nano-order scale defective parts (pinholes) on the surface of the stainless steel base material in which a corrosion-resistant conductive layer, and particularly, a titanium layer, is not formed, and the passive layer can minimize metal elution from the stainless steel base material, that is, can improve corrosion resistance and reduce contact resistance.

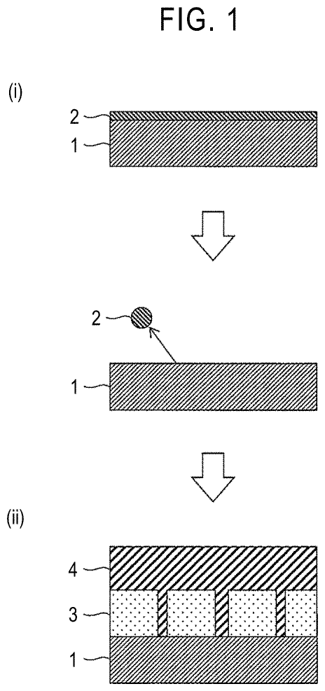

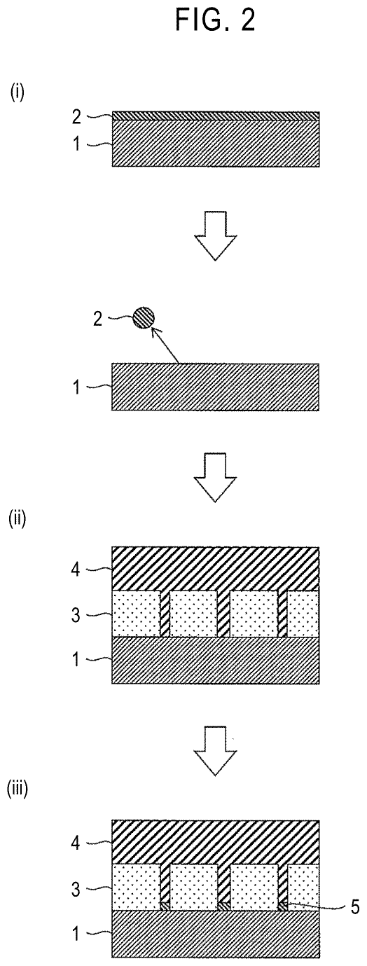

FIG. 1 schematically shows a method of forming a layer having corrosion resistance and a layer having conductivity on a stainless steel base material in the related art, and FIG. 2 schematically shows a method of forming a layer having corrosion resistance and a layer having conductivity on a stainless steel base material of the present disclosure.

In FIG. 1, which shows the method in the related art, first, in the process (i), a passive layer 2 present on the surface of the prepared stainless steel base material 1 is removed. Subsequently, in the process (ii), a layer 3 having corrosion resistance and a layer 4 having conductivity are formed on the surface of the passive-layer-removed stainless steel base material 1 from which the passive layer 2 has been removed in the process (i).

On the other hand, in FIG. 2, which shows the present disclosure, first, in the process (i), the passive layer 2 present on the surface of the prepared stainless steel base material 1 is removed. Subsequently, in the process (ii), a layer 3 having corrosion resistance and a layer 4 having conductivity are formed on the surface of the passive-layer-removed stainless steel base material 1 from which the passive layer 2 has been removed in the process (i). Finally, in the process (iii), the corrosion-resistant conductive layers 3 and 4-formed stainless steel base material 1 is annealed in a certain temperature range under conditions of oxygen being contained, and a passive layer 5 is newly formed on defective parts (pinholes) on the surface of the corrosion-resistant conductive layers 3 and 4-formed stainless steel base material 1 in which the corrosion-resistant conductive layers 3 and 4, and particularly, the layer 3 having corrosion resistance, are not formed. When the process (iii) is performed, the passive layer 5 can minimize metal elution from the stainless steel base material 1, that is, can improve corrosion resistance and reduce contact resistance.

The separator for a fuel cell produced according to the present disclosure can be used in a fuel cell, and the fuel cell containing the separator can be used in various electrochemical devices such as a solid polymer fuel cell.

Several examples related to the present disclosure will be described below. However, this is not intended to limit the present disclosure to that described in such examples.

### 1. Sample Preparation

A titanium layer and a carbon layer were formed on a stainless steel base material by a PVD method under conditions shown below to prepare a titanium layer-deposited and carbon layer-deposited stainless steel base material.

### Titanium Layer Film Formation Conditions

Film formation was performed using a sputtering method. The film formation was performed when an atmosphere temperature in a furnace was set to 150° C. using a heater in the furnace, the flow rate of Ar gas was adjusted, and thus the pressure in the furnace was set to 0.05 Pa, and a negative bias voltage was applied to a film-forming substrate.

### Carbon Layer Film Formation Conditions

Film formation was performed by an AIP method. The film formation was performed when the flow rate of Ar gas was adjusted and thus the pressure in the furnace was set to 0.05 Pa, and a negative bias voltage was applied to a film-forming substrate.

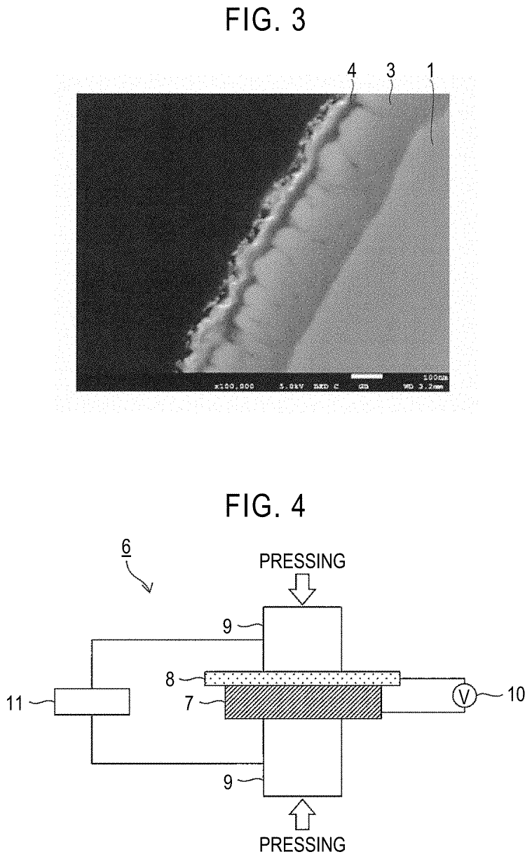

FIG. 3 shows an TEM image of the obtained titanium layer 3- and carbon layer 4-deposited stainless steel base material 1.

It was found in FIG. 3 that there were defective parts in the titanium layer 3.

Subsequently, the obtained titanium layer-deposited and carbon layer-deposited stainless steel base material in which there were defective parts in the titanium layer was annealed in the air at 100° C. (Comparative Example 2), 250° C. (Example 1), 400° C. (Example 2), 550° C. (Comparative Example 3), or 700° C. (Comparative Example 4) for 60 minutes. Table 1 shows the obtained experimental products. Here, Comparative Example 1 was a sample that was not annealed.

TABLE 1
Annealing condition table (atmospheric environment)

| Sample name | Temperature (° C.) | Retention time (min) |
|---|---|---|
| Comparative Example 1 | — | — |
| Comparative Example 2 | 100 | 60 |
| Example 1 | 250 | 60 |
| Example 2 | 400 | 60 |
| Comparative Example 3 | 550 | 60 |
| Comparative Example 4 | 700 | 60 |

### 2. Analysis

The contact resistances of the obtained Comparative Examples 1 to 4 and Examples 1 and 2 were measured, and the elution amounts of Comparative Example 1 and Example 1 were measured.

### Measurement of Contact Resistance

The contact resistances of Comparative Examples 1 to 4 and Examples 1 and 2 were measured using a contact resistance measurement device 6 schematically shown in FIG. 4.

A gas diffusion layer film 8 of a power generation unit of a fuel cell was disposed on one side of each test piece 7. Next, an electrode 9 was provided outside the test piece 7 and the gas diffusion layer film 8, and a constant load (1.0 MPa) of pressure was applied to the surface of the test piece 7. In this state, while a current flowing through the test piece 7 was adjusted with an ammeter so that it became constant, a current flowed from a DC current power supply 11 connected to the electrode 9. A voltage applied to the test piece 7 was measured with a voltmeter 10, and the contact resistance between the test piece 7 and the gas diffusion layer film 8 was calculated.

### Measurement of Elution Amount

The elution amounts of Comparative Example 1 and Example 1 were measured by a constant potential corrosion test according to the electrochemical high temperature corrosion test method (JISZ2294) of metal materials of Japanese Industrial Standards.

Specifically, while each sample (Comparative Example 1 or Example 1) was immersed in a sulfuric acid aqueous solution adjusted to a temperature of 80° C., a potential of 0.9 Vvs SHE was kept constant, after the constant potential corrosion test, the amount of metal elution of metal base material components of the separator eluted in the sulfuric acid aqueous solution was measured by an ICP analysis device from a difference in amounts of metal in the solution before and after the test. Here, for the sulfuric acid aqueous solution, a solution in which NaF was dissolved was used so that the fluoride ion concentration was 3.0 ppm. In addition, the time of the constant potential corrosion test was 60 hours.

### 3. Evaluation Results

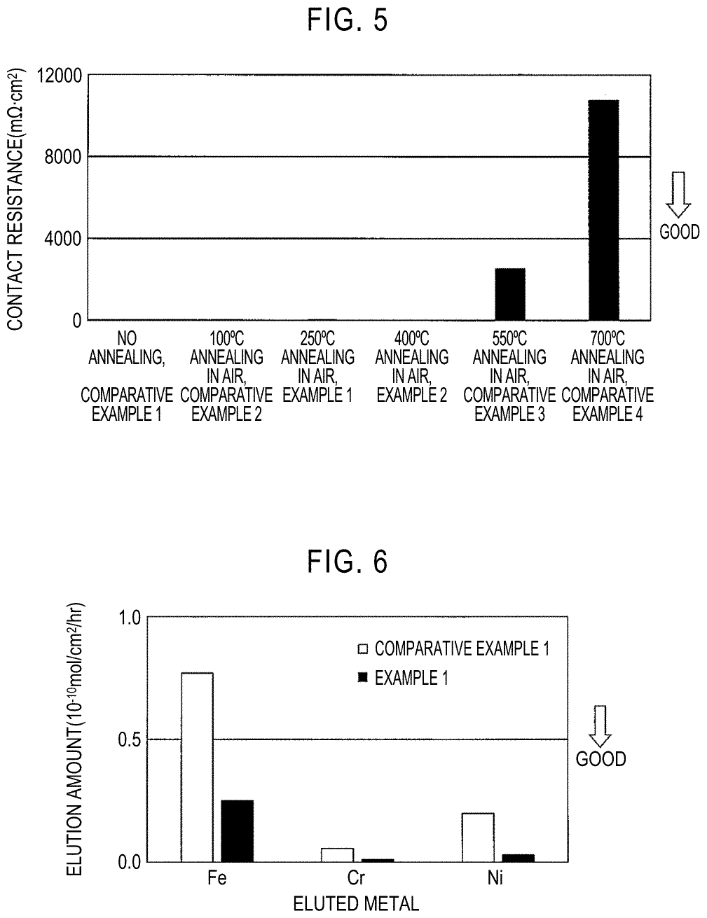

FIG. 5 and Table 2 show the contact resistances of Comparative Examples 1 to 4 and Examples 1 and 2.

TABLE 2
Contact resistance between GDL

| | | Contact |
|---|---|---|
| Sample name | Annealing conditions | resistance |
| Comparative Example 1 | No annealing | 1.3 |
| Comparative Example 2 | 100° C.-1 hr, annealing in air | 1.4 |
| Example 1 | 250° C.-1 hr, annealing in air | 1.7 |
| Example 2 | 400° C.-1 hr, annealing in air | 3.2 |
| Comparative Example 3 | 550° C.-1 hr, annealing in air | 2527 |
| Comparative Example 4 | 700° C.-1 hr, annealing in air | 10757 |

It was found in FIG. 5 and Table 2 that, when the temperature of the annealing treatment was 550° C. or higher, contact resistance sharply increased. Therefore, it was found that the temperature of the annealing treatment was lower than 550° C., and preferably 400° C. or lower in consideration of contact resistance.

FIG. 6 and Table 3 show the elution amounts of Comparative Example 1 and Example 1.

TABLE 3
Elution amount

| | Annealing | Elution amount (10⁻¹⁰ mol/cm²/hr) | | |
|---|---|---|---|---|
| Sample name | conditions | Fe | Cr | Ni |
| Comparative | No annealing | 0.770 | 0.056 | 0.199 |
| Example 1 | | | | |
| Example 1 | 250° C.-1 hr, | 0.251 | 0.011 | 0.030 |
| | annealing in air | | | |

It was found in FIG. 6 and Table 3 that, when the annealing treatment was performed at 250° C., the elution amount of each metal was reduced as compared with when the annealing treatment was not performed. Therefore, it was found that the temperature of the annealing treatment was preferably 250° C. or higher in consideration of the elution amount.

Based on the above results, it was found that the annealing treatment was performed at 250° C. or higher and lower than 550° C., and preferably a temperature of 250° C. to 400° C.

What is claimed is:

1. A method of producing a separator for a fuel cell in which layers having corrosion resistance and conductivity are formed on a stainless steel base material, the method comprising:
(i) a process of removing a passive layer on a surface of a stainless steel base material to obtain a stainless steel base material from which the passive layer has been removed,
(ii) a process of forming layers having corrosion resistance and conductivity on the surface of the stainless steel base material from which the passive layer has been removed to obtain a corrosion-resistant conductive layer-deposited stainless steel base material, and
(iii) a process of annealing the corrosion-resistant conductive layer-deposited stainless steel base material in a temperature range of 250° C. or higher and lower than 550° C. under conditions of oxygen being contained.

2. The method according to claim 1,
wherein, in the process (iii), the annealing treatment is performed at 250° C. to 400° C.

3. The method according to claim 1,
wherein the process (ii) includes
(ii-1) a process of forming a titanium layer on the surface of the stainless steel base material from which the passive layer has been removed to obtain a titanium layer-deposited stainless steel base material, and
(ii-2) a process of forming a carbon layer on the surface of the titanium layer-deposited stainless steel base material to obtain a titanium layer-deposited and carbon layer-deposited stainless steel base material.

4. The method according to claim 1,
wherein, in the process (ii), the layers having corrosion resistance and conductivity are formed by a physical vapor deposition method.
